(19) United States
(12) Patent Application Publication
(10) Pub. No.: US 2025/0022528 A1
(43) Pub. Date: Jan. 16, 2025

(54) HEAT GENERATION CONTROL FOR MEMORY SYSTEM EVALUATION

(71) Applicant: Micron Technology, Inc., Boise, ID (US)

(72) Inventors: Natalia Tarazona Cordoba, Munich (DE); Ken Choong Lim, Munich (DE); Kari Lin Crane, Boise, ID (US)

(21) Appl. No.: 18/742,097

(22) Filed: Jun. 13, 2024

Related U.S. Application Data
(60) Provisional application No. 63/526,101, filed on Jul. 11, 2023.

(51) Int. Cl. G11C 29/44; G01R 31/28; G11C 11/413; G11C 29/12

(52) U.S. Cl. CPC G11C 29/44; G01R 31/2849; G11C 11/413; G11C 29/12005

(57) ABSTRACT

Methods, systems, and devices for heat generation control for semiconductor component evaluations are described. A semiconductor component may be subject to evaluation procedures and may include memory arrays, temperature sensors, and circuitry to cause the semiconductor component to perform one or more operations. The semiconductor component may receive an indication to operate in an evaluation mode and may be configured to operate according to a first evaluation mode. The semiconductor component may perform first evaluation operations in accordance with the first evaluation mode. The semiconductor component may be configured to operate in a second evaluation mode based on a temperature satisfying a temperature threshold in response to performing the first evaluation operations. The semiconductor component may perform second evaluation operations in accordance with the second evaluation mode.

### CROSS REFERENCE

The present Application for Patent claims the benefit of U.S. Provisional Patent Application No. 63/526,101 by TARAZONA CORDOBA et al., entitled “HEAT GENERATION CONTROL FOR MEMORY SYSTEM EVALUATION,” filed Jul. 11, 2023, assigned to the assignee hereof, and expressly incorporated by reference in its entirety herein.

### TECHNICAL FIELD

The following relates to one or more systems for memory, including heat generation control for memory system evaluation.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports heat generation control for memory system evaluation in accordance with examples as disclosed herein.

FIG. 2 shows an example of an evaluation system that supports heat generation control for memory system evaluation in accordance with examples as disclosed herein.

FIG. 3 shows an example of a system that supports heat generation control for memory system evaluation in accordance with examples as disclosed herein.

FIG. 4 shows a block diagram of a semiconductor component that supports heat generation control for memory system evaluation in accordance with examples as disclosed herein.

FIG. 5 shows a flowchart illustrating a method or methods that support heat generation control for memory system evaluation in accordance with examples as disclosed herein.

### DETAILED DESCRIPTION

Some evaluation procedures (e.g., elevated temperature testing, burn testing) may evaluate operating performance of test articles (e.g., semiconductor components such as memory systems, memory devices, memory dies, memory wafers) in high-temperature environments. Such evaluation procedures may evaluate whether test articles will fail or otherwise operate adversely when operating in high temperatures. In some cases, multiple test articles may be placed together in a temperature chamber (e.g., a test oven) for evaluation, and each test article may be expected to reach or exceed a target temperature while performing operations in order to satisfy a high-temperature evaluation. However, some of the test articles may experience higher article temperatures than others due to inconsistent chamber temperatures, different heat generation among the test articles, or various combinations of these and other factors. As such, to reach a target temperature for each test article, some test articles may exceed an upper temperature threshold, causing the test article to cease (e.g., suspend) evaluation operations. Accordingly, the test article may fail the evaluation and may be subject to additional evaluation attempts, which may decrease efficiency of evaluation procedures. In some examples, a test article may experience component damage due to such elevated temperatures, which may result in rejection of the test article, thereby decreasing production yield of articles under evaluation.

In accordance with various techniques disclosed herein, a test article (e.g., a semiconductor component) may be configured to operate in accordance with a reduced heat generation evaluation mode to increase a likelihood of satisfying criteria of an evaluation procedure. For example, a test article may detect when a temperature of the test article satisfies (e.g., meets or exceeds) an intermediate temperature threshold that is lower than an upper temperature threshold for an evaluation procedure. Based on detecting that the test article temperature satisfies the intermediate threshold, the test article may adjust its operating characteristics to reduce heat generation associated with its operations.

In some examples, the test article may adjust its operating characteristics by adjusting a threshold voltage characteristic of one or more transistors of the test article. For example, the test article may implement a back-biasing of one or more transistor wells with a non-zero or an otherwise modified (e.g., increased) voltage. Such back-biasing may result in reduced current flow through the one or more transistors of the test article, thereby reducing associated heat generation of the test article. Adjusting evaluation operating characteristics in accordance with the described techniques may reduce test article damage related to overheating during evaluation procedures, which may decrease reevaluation of test articles and improve evaluation efficiency and production yield.

Features of the disclosure are illustrated and described in the context of systems, such as systems that include a memory system and a host system. Features of the disclosure are further illustrated and described in the context of components, evaluation configurations, block diagrams, and flowcharts.

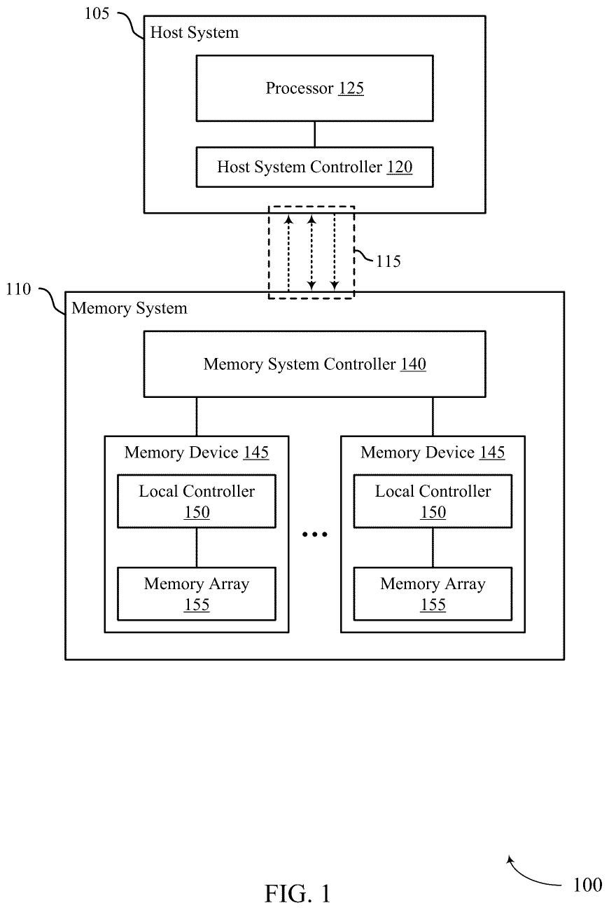

FIG. 1 illustrates an example of a system 100 that supports heat generation control for memory system evaluation in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some cases, an electronic test article may undergo evaluation procedures to evaluate operating performance in high-temperature environments. Such evaluation procedures may test whether a test article will fail while operating in high temperatures. However, multiple test articles may be evaluated at a time, and some test articles may experience higher article temperatures than other test articles (e.g., due to inconsistent chamber temperatures, due to different heat generation among the test articles, or both). As such, some test articles may exceed a maximum temperature threshold, causing the test article to cease (e.g., suspend) evaluation operations and fail the evaluation. Accordingly, the test article may be subject to additional evaluation attempts and, in some examples, may experience component damage due to such elevated temperatures.

In accordance with various techniques disclosed herein, a test article (e.g., a semiconductor component, such as a memory system 110, a memory device 145, or a host system 105, or any component thereof) may be configured to operate in accordance with a reduced heat generation evaluation mode to decrease a likelihood of the test article failing criteria of an evaluation procedure or experiencing component damage. In some examples, a test article may detect when a temperature of the test article satisfies a temperature threshold that is lower than a maximum temperature threshold for an evaluation procedure but higher than a minimum threshold for the evaluation procedure. In some examples, the test article may adjust (e.g., modify, increase) a threshold voltage characteristic of one or more transistors (e.g., transistor wells) of the test article, which may result in reduced heat generation of the test article (e.g., based on a reduced current flow in the test article). Operating a test article in the reduced heat generation evaluation mode, in accordance with the described techniques, may reduce overheating of the test article and increase a likelihood of the test article satisfying criteria of an evaluation procedure, thereby improving evaluation efficiency and production yield.

In addition to applicability in systems as described herein, techniques for heat generation control for memory system evaluation may be generally implemented to improve the sustainability of various electronic devices and systems. As the use of electronic devices has become increasingly widespread, the amount of energy used and environmental implications associated with production of electronic devices and device operation has increased. Further, waste associated with disposal of electronic devices may also be detrimental for various reasons. Implementing the techniques described herein may reduce impacts related to electronic devices by reducing materials used in production of electronic devices and eliminating repeated evaluation processes, which may result in reduced electronic waste and lowered production emissions, among other benefits.

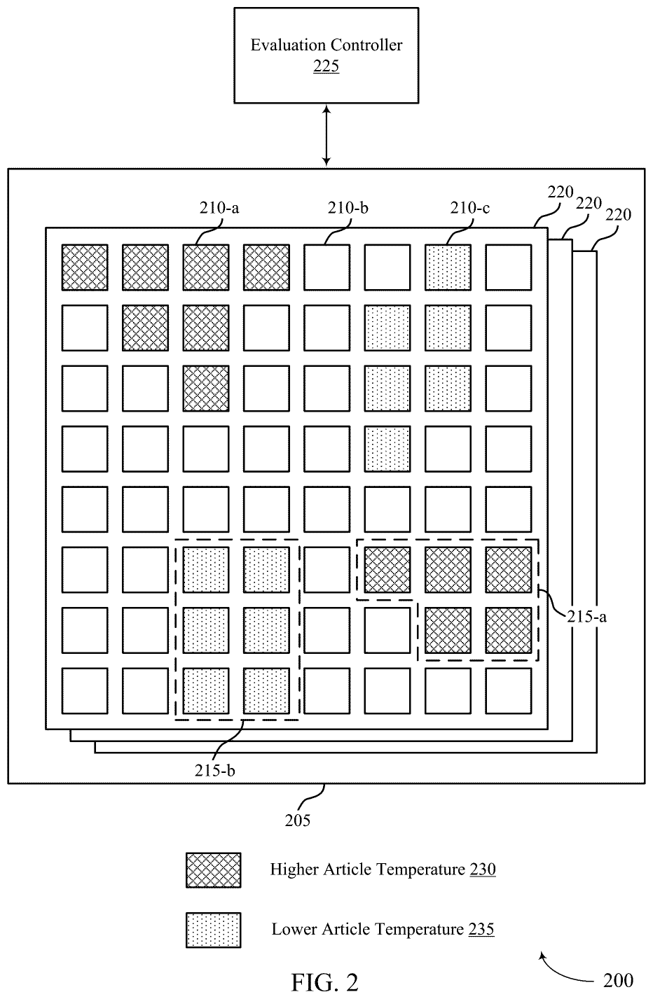

FIG. 2 shows an example of an evaluation system 200 that supports heat generation control for memory system evaluation in accordance with examples as disclosed herein. The evaluation system 200 may include a set of test articles 210 in a chamber 205 (e.g., an evaluation chamber, a temperature chamber, a test oven), one or more of which may be operated at least in part by an evaluation controller 225. Each square may represent a respective test article 210 (e.g., a device under test (DUT)), each of which may be an example of or include a semiconductor component such as a semiconductor wafer or a semiconductor die. In various examples, a test article 210 may be an example of or include a memory system 110 (e.g., a packaged memory system), a memory device 145 (e.g., a packaged memory device, a memory die), a host system 105, or a portion thereof or a combination thereof. A chamber 205 may include any quantity of one or more arrays 220 of test articles 210. For example, each array 220 may be associated with a respective set of test articles 210 that are placed on (e.g., coupled with) a corresponding evaluation device (e.g., evaluation boards, burn-in-boards), or are a constituent portions of a larger semiconductor component (e.g., test articles 210 being associated with semiconductor dies to be separated from a semiconductor wafer associated with the array 220), and the respective arrays 220 may be placed together in a chamber 205 for one or more evaluations. In some examples, each test article 210 may be controlled independently by its own respective components (e.g., internal circuitries, sensors).

In some cases, an evaluation controller 225 may be coupled with the chamber 205. In various examples, the evaluation controller 225 may be an example of a host system and may communicate with the chamber 205, components within the chamber 205 (e.g., evaluation devices, test articles 210), or both. For example, the evaluation controller 225 may transmit access signaling (e.g., one or more access commands, evaluation routine instructions, or other commands) and may receive responsive signaling (e.g., data from access operations, indications from a test article 210, signaling indicating whether an evaluation route was performed successfully) based on transmitting the access signaling.

The test articles 210 may be placed in the chamber 205 for an evaluation procedure (e.g., operational stress testing, burn testing), and each test article 210 may enter an evaluation mode (e.g., based on receiving an indication from the evaluation controller 225). The evaluation procedure may include elevating a temperature of the chamber 205 while the test articles 210 perform one or more operations (e.g., internal operations of the test articles 210, memory access operations). In some cases, the evaluation procedure may ensure that the test articles 210 operate in accordance with expectation at the elevated temperature (e.g., as part of design validation testing, as part of manufacturing validation, to ensure that manufactured parts are suitable for final assembly). To satisfy (e.g., pass) the evaluation procedure, the test articles 210 may be expected to satisfy (e.g., reach, exceed) at least a target temperature threshold (e.g., a minimum temperature, a temperature threshold for elevated-temperature evaluations) associated with the evaluation procedure. For example, if a test article 210 fails to reach the target temperature threshold, it may fail the evaluation procedure.

In some cases, respective temperatures for different regions 215 of the chamber 205, or different test articles 210, or both may not be uniform across the chamber 205. For example, there may be some regions 215 of the chamber 205, or some test articles 210, or both that have a higher temperature than (e.g., are hotter than) than other regions 215 or other test articles 210. In some examples, test articles 210 in a region 215-a may be associated with a higher article temperature 230 and test articles 210 in a region 215-b may be associated with a lower article temperature 235 (e.g., due inconsistent chamber temperatures, due to inconsistent heat generation of the test articles 210 in the region 215). Such temperature inconsistencies may result in some test articles 210 in a chamber 205 exceeding an upper temperature threshold (e.g., a maximum temperature, an over-temperature) associated with an evaluation procedure, while some other test articles 210 in the chamber 205 may fail to reach a lower temperature threshold (e.g., the target temperature threshold) associated with the evaluation procedure.

In some examples, if a temperature of a test article 210 exceeds an upper temperature threshold, the test article 210 may experience an overheat condition (e.g., thermal runaway) in which the test article 210 may generate more heat than the test article 210 can dissipate. In some cases, such conditions may result in damage to the test article 210 (e.g., and components within the test article 210). For instance, a test article 210-a may be associated with the higher article temperature 230 and experience thermal runaway. As a result, one or more portions of the test article 210-a may physically deform (e.g., warp, crack), or components of the test article 210-a may overheat and fail (e.g., detach, burn, melt), among other high-temperature failures.

In some cases, a test article 210 that exceeds the upper temperature threshold may cease (e.g., suspend, stop) evaluation operations to cease further heat generation and mitigate component damage. Thus, the test article 210 may fail the evaluation procedure and may be subject to an additional evaluation procedure (e.g., a reevaluation of the test article 210) or may be discarded based on potential or experienced component damage (e.g., due to irreparable component damage). In some other cases, a test article 210 that fails to reach the lower temperature threshold may fail the evaluation procedure and may be subject to an additional evaluation procedure (e.g., a reevaluation of the test article 210 to satisfy a lower temperature threshold).

In an illustrative example, a test article 210-a may be associated with the higher article temperature 230 and may satisfy an upper temperature threshold. Accordingly, the test article 210-a may fail an evaluation procedure and may be discarded or may be subject to additional evaluation procedures (e.g., retesting). A test article 210-b may be associated with a normal article temperature (e.g., an intermediate temperature between the higher article temperature 230 and a lower article temperature 235), and may operate according to expectation. Accordingly, the test article 210-b may satisfy the evaluation procedure (e.g., may satisfy operating expectations as part of design validation testing). A test article 210-c may be associated with the lower article temperature 235 and may fail to satisfy a lower temperature threshold. Accordingly, the test article 210-c may fail to satisfy the evaluation procedure any may be subject to additional evaluation procedures. Such variation of temperature between test articles 210 in a same evaluation procedure may result in decreased efficiency of evaluation procedures and a reduced production yield.

In accordance with techniques describes herein, a test article 210 (e.g., a semiconductor component) may be configured to operate in a reduced heat generation operating mode. In some examples, the test article 210 may operate in the reduced heat generation mode based on a temperature indicated by one or more temperature sensors of the test article 210 satisfying a temperature threshold (e.g., a back-bias temperature threshold) while performing one or more evaluation operations. The temperature threshold may be configured (e.g., programmed, set, preconfigured) to be higher than a target temperature threshold for an evaluation procedure, but lower than an upper temperature threshold (e.g., associated with thermal runaway). The reduced heat generation mode may be associated with the test article 210 modifying (e.g., increasing) a threshold voltage characteristic for one or more transistors (e.g., back-biasing one or more transistors, or wells thereof), among other configurations that may reduce electrical current and corresponding heat generation in the test article 210.

For example, a test article 210-a and a test article 210-b may be placed in a chamber 205 for an evaluation procedure. The test article 210-a and the test article 210-b may receive respective indications (e.g., from an evaluation controller 225) to operate in an evaluation mode (e.g., a mode for performing evaluation operations such as memory access operations or other internal operations). Accordingly, the test article 210-a and the test article 210-b may configure their respective components to operate in a first evaluation mode (e.g., a nominal evaluation mode, a baseline evaluation mode) and may begin performing respective evaluation operations for the evaluation procedure. In response to performing the evaluation operations, one or more temperature sensors at the test article 210-a may indicate that a temperature of the test article 210-a satisfies a temperature threshold (e.g., the back-bias temperature threshold), and the test article 210-a may be configured to operate in a second evaluation mode (e.g., a reduced heat generation evaluation mode). Temperature sensors of the test article 210-b, however, may indicate that a temperature of the test article 210-b fails to satisfy the temperature threshold in response to performing the evaluation operations, and the test article 210-b may refrain from operating in the second evaluation mode (e.g., may continue to operate in the first evaluation mode).

Configuring test articles 210 to operate in an evaluation mode (e.g., a reduced heat generation mode) based on a temperature threshold may enable each test article 210 to individually adjust heat generation to both reach a target temperature and avoid exceeding an upper temperature threshold. Such techniques may result in improved production yield (e.g., due to an increased quantity of test articles satisfying criteria of an evaluation procedure) and improved efficient in evaluation procedure (e.g., due to reduce reevaluation of failed test articles 210).

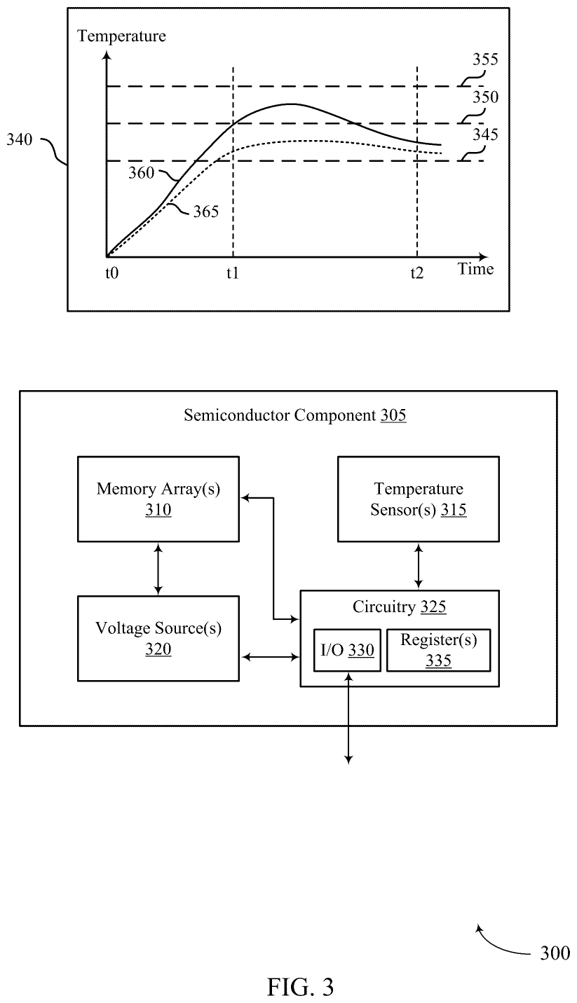

FIG. 3 shows an example of a system 300 that supports heat generation control for memory system evaluation in accordance with examples as disclosed herein. The system 300 may include a semiconductor component 305 with one or more subcomponents such as one or more memory arrays 310, one or more temperatures sensors 315, one or more voltage sources 320, and circuitry 325. The semiconductor component 305 may be an example of or include a memory system 110 (e.g., a packaged memory system), a memory device 145 (e.g., a packaged memory device, a memory die), a host system 105, or a portion thereof or a combination thereof, or a test article 210. A graph 340 may illustrate examples of temperatures (e.g., measurements or calculations based on readings the one or more temperatures sensors 315) of a semiconductor component 305 over time during examples of evaluation procedures.

In some examples, the semiconductor component 305 may subject to evaluation procedures (e.g., burn testing, temperature stress testing) for validation during a production process. During an evaluation procedure the semiconductor component 305 may be coupled with one or more other semiconductor components 305 (e.g., placed on a shared evaluation device, such as a burn-in-board, or included in a common semiconductor wafer). The semiconductor component 305 may be placed in an evaluation chamber (e.g., a chamber 205), which may elevate a temperature (e.g., an ambient temperature) for the evaluation procedure. However, due to non-uniform conditions (e.g., inconsistent temperatures throughout the chamber, inconsistent heat generation among different semiconductor components 305), some semiconductor components 305 may experience higher or lower temperatures than other semiconductor components 305, which may result in component damage (e.g., due to overheating), repeated evaluation procedures (e.g., due to failure of the evaluation procedure), or both, among other adverse effects. In accordance with examples as disclosed herein, a semiconductor component 305 may dynamically adjust its heat generation based on comparing a temperature of the semiconductor component 305 to one or more temperature thresholds.

The circuitry 325 may be coupled with or operable to couple with the one or more memory arrays 310, the one or more temperatures sensors 315, and the one or more voltage sources 320 (e.g., via one or more internal buses). The circuitry 325 also may be coupled with an external device (e.g., an evaluation system 200, a host system 105, an evaluation controller 225) via input/output (I/O) circuitry 330. In some examples, the circuitry 325 may cause (e.g., configure) the semiconductor component 305 to perform one or more operations as described herein. For example, the circuitry 325 may configure the semiconductor component 305 to operate in one or more evaluation operating modes (e.g., test modes) and perform one or more operations (e.g., evaluation operations) in accordance with an evaluation operating mode. In some examples, the circuitry 325 may be an example of or include one or more of a memory system controller 140, a local controller 150, a processor 125, a host system controller 120, or any combination thereof.

In some examples, the circuitry 325 may receive an indication to operate in an evaluation mode (e.g., from an evaluation system 200, from an evaluation controller 225). Based on receiving the indication, the circuitry 325 may configure the semiconductor component 305 to operate in a first evaluation mode (e.g., a nominal evaluation mode, an initial operating mode). Accordingly, the semiconductor component 305 (e.g., the circuitry 325) may perform one or more first operations (e.g., evaluation operations, test operations) in accordance with the first evaluation mode, which may be responsive to commands or instructions from an evaluation controller 225 of an evaluation system 200. In some examples, the one or more first operations may include evaluation operations such as accessing (e.g., read operations, write operations) the one or more memory arrays 310 (e.g., memory cells in the one or more memory arrays 310), internal operations of the semiconductor component 305, other operations, or any combination thereof.

Performing evaluation operations may result in an increase in temperature of the semiconductor component 305 (e.g., due to electrical current and power consumption associated with operating the semiconductor component 305). In some examples, a temperature of the semiconductor component 305 may satisfy (e.g., meet or exceed) one or more temperature thresholds (e.g., a temperature threshold 345, a temperature threshold 350, a temperature threshold 355) based on performing evaluation operations. In some examples, a semiconductor component 305 may be expected to reach at least a temperature threshold 345 (e.g., a target temperature threshold, a minimum temperature) to satisfy an evaluation procedure. In some examples, the semiconductor component 305 may be expected to remain below a temperature threshold 355. For instance, exceeding the temperature threshold 355 may cause the semiconductor component 305 to cease evaluation operations to mitigate potential damage to the semiconductor component 305 from overheating conditions (e.g., thermal runaway). For example, in a successful evaluation operation, a temperature of the semiconductor component 305 may remain between the temperature threshold 345 and the temperature threshold 355 during at least a portion of the evaluation operation.

In some implementations, the circuitry 325 may be configured to compare one or more temperatures indicated by one or more temperatures sensors 315 to a temperature threshold 350 (e.g., an intermediate temperature threshold) that is higher than the temperature threshold 345 and lower than the temperature threshold 355. The one or more temperatures sensors 315 may monitor one or more temperatures of the semiconductor component 305 and may indicate the one or more temperatures to the circuitry 325 during the evaluation procedure. In some examples, the one or more temperatures sensors 315 may indicate one or more temperatures according to a periodicity (e.g., 1 millisecond), or based on a request from the circuitry 325, or both. The circuitry 325 may compare temperatures indicated by the one or more temperatures sensors 315 to the temperature thresholds (e.g., temperature threshold 345, temperature threshold 350, and temperature threshold 355), and may determine whether a temperature satisfies any of the temperature thresholds based on the comparing.

Based on at least one of the one or more temperatures satisfying the temperature threshold 350 (e.g., in response to performing the one or more first operations), the circuitry 325 may configure the semiconductor component 305 to operate in a second evaluation mode (e.g., a reduced heat generation mode). For example, the circuitry 325 (e.g., or another component of the semiconductor component 305) may set a value of a flag (e.g., a bit) in one or more registers 335 based on a temperature satisfying the temperature threshold 350. In such examples, configuring the semiconductor component 305 to operate in the second evaluation mode may be based on the value of the flag. The second evaluation mode may be associated with a lower heat generation the first evaluation mode (e.g., the initial operating mode). The semiconductor component 305 (e.g., the circuitry 325) may perform one or more second operations (e.g., evaluation operations, test operations) in accordance with the second evaluation mode based on being configured to operate in the second evaluation mode. In some examples, the circuitry 325 may transmit an indication (e.g., to an external device, to an evaluation controller 225 of an evaluation system 200, via the I/O circuitry 330) that the semiconductor component 305 is configured to operate in the second evaluation operating mode, or that a temperature of semiconductor component 305 has satisfied the temperature threshold 350.

In some examples, the circuitry 325 may configure the semiconductor component 305 to operate in the second evaluation mode by controlling a back-bias setting of the semiconductor component 305. Thus, the temperature threshold 350 may, in some examples, be referred to as a back-bias threshold or a back-bias temperature threshold. Controlling the back-bias setting may be associated with increasing a threshold voltage (e.g., a Vₜ value, a Vₜₕ value) for one or more transistors of the semiconductor component 305 (e.g., transistors of the one or more memory arrays 310, transistors of the circuitry 325). For example, increasing the threshold voltage for one or more transistors may include increasing a bias, from the one or more voltage sources 320, that is applied to one or more wells of the semiconductor component 305 associated with the one or more transistors. In some examples, increasing a threshold voltage for a transistor may modify a conductivity of the transistor, such as by modulating (e.g., increasing) a voltage (e.g., a gate voltage) to activate the transistor. Modulating the threshold voltage of the one or more transistors of the semiconductor component 305 may reduce power consumption (e.g., and flow of electrical current), thereby reducing heat generation in the semiconductor component 305. However, in some other examples, other techniques may be implemented to change a threshold voltage characteristic, or otherwise reduce a heat generation (e.g., reduce a current flow, reduce a power consumption) associated with operations of the semiconductor component 305.

The circuitry 325 may increase a bias for all transistors of the semiconductor component 305 or for a subset of transistors of the semiconductor component 305 (e.g., based on different readings from different temperature sensors 315, based on which transistors may be associated with heat generation, based on transistors for which a threshold voltage characteristic may be modified). For example, the circuitry 325 may increase a first bias for a first subset of wells associated with a first subset transistors of the semiconductor component 305 based on a temperature indicated by one or more first temperature sensors and may maintain a second bias for a second subset of wells associated with a second subset transistors of the semiconductor component 305 based on a temperature indicated by one or more second temperature sensors.

In some examples, a semiconductor component 305 may exceed the temperature threshold 355, which may be associated with an upper temperature threshold (e.g., may be greater than the temperature threshold 350) for an evaluation procedure. In some examples, the circuitry 325 may configure the semiconductor component 305 to cease evaluation operations (e.g., the circuitry 325 may cease performing evaluation operations) based on a temperature indicated by the one or more temperatures sensors 315 satisfying the temperature threshold 355 (e.g., to cease heat generation and mitigate damage to the semiconductor component 305). In some examples, the circuitry 325 may transmit an indication (e.g., to an external device, to an evaluation controller 225, via the I/O circuitry 330) that the semiconductor component 305 is configured to cease evaluation operations.

In the examples illustrated by the graph 340, an evaluation procedure may begin at time t0. The curve 360 may illustrate a temperature (e.g., a temperature reading associated with one or more temperature sensors 315) of a first semiconductor component 305 and the curve 365 may illustrate a temperature of a second semiconductor component 305 over a duration of the evaluation procedure. In some examples, the first semiconductor component 305 and the second semiconductor component 305 may be placed in a same chamber (e.g., a chamber 205) for the evaluation procedure, which may include the first semiconductor component 305 and the second semiconductor component 305 being members of a same array 220 or of different arrays 220.

At time t0, the first semiconductor component 305 and the second semiconductor component 305 may be configured to perform one or more first evaluation operations according to a first evaluation mode. The temperature of the first semiconductor component 305 and the second semiconductor component 305 may accordingly increase over time. At time t1, the temperature of the first semiconductor component 305 may satisfy a temperature threshold 350 (e.g., a back-bias temperature threshold). In response, circuitry 325 of the first semiconductor component 305 may configure the first semiconductor component 305 to operate in a second evaluation mode (e.g., a reduced heat generation mode), which may include controlling a back-bias setting of the first semiconductor component 305. Based on operating in the second evaluation mode, heat generation of the first semiconductor component 305 may decrease, such that a temperature of the first semiconductor component 305 may stabilize or decrease before (e.g., without) reaching the temperature threshold 355. As illustrated by the curve 365, the temperature of the second semiconductor component 305 may not satisfy the temperature threshold 350, and the second semiconductor component 305 may accordingly continue to operate according to the first evaluation mode during the evaluation procedure (e.g., without operating in a reduced heat generation mode, without controlling or adjusting a back-bias setting). At time t2, the evaluation procedure may complete, and both the first semiconductor component 305 and the semiconductor component 305 may satisfy the evaluation procedure based on satisfying operation expectations, satisfying at least the temperature threshold 345 (e.g., a target temperature), and refraining from reaching the temperature threshold 355.

Controlling the back-bias setting, as described herein, may enable a semiconductor component 305 to dynamically control its temperature during an evaluation procedure. Thus, the semiconductor component 305 may compensate (e.g., dynamically, autonomously) for non-uniform evaluation conditions (e.g., inconsistent chamber temperatures), thereby reducing a potential for component damage (e.g., due to thermal runaway) and increasing a likelihood of satisfying the evaluation procedure (e.g., satisfying criteria of the evaluation procedure). Accordingly, efficiency of evaluation procedures may increase, resulting in an increased production yield of manufacturing processes.

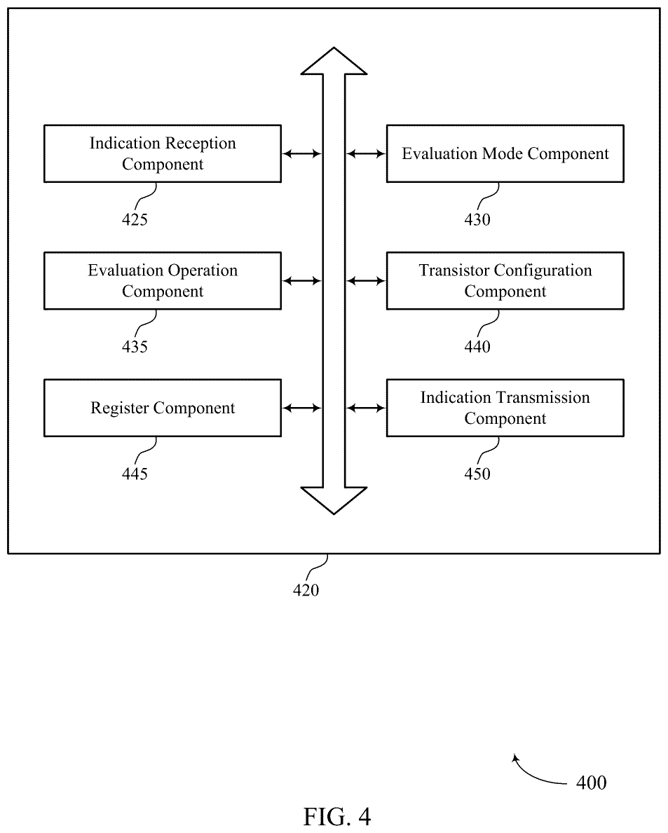

FIG. 4 shows a block diagram 400 of a semiconductor component 420 that supports heat generation control for memory system evaluation in accordance with examples as disclosed herein. The semiconductor component 420 may be an example of aspects of a semiconductor component as described with reference to FIGS. 1 through 3. The semiconductor component 420, or various components thereof, may be an example of means for performing various aspects of heat generation control for memory system evaluation as described herein. For example, the semiconductor component 420 may include an indication reception component 425, an evaluation mode component 430, an evaluation operation component 435, a transistor configuration component 440, a register component 445, an indication transmission component 450, or any combination thereof. Each of these components, or components of subcomponents thereof (e.g., one or more processors, one or more memories), may communicate, directly or indirectly, with one another (e.g., via one or more buses).

The indication reception component 425 may be configured as or otherwise support a means for receiving, at the semiconductor component 420, an indication to operate in an evaluation mode. The evaluation mode component 430 may be configured as or otherwise support a means for configuring the semiconductor component 420 to operate in a first evaluation mode based at least in part on receiving the indication. The evaluation operation component 435 may be configured as or otherwise support a means for performing one or more first operations of the semiconductor component 420 based at least in part on configuring the semiconductor component 420 to operate in the first evaluation mode. In some examples, the evaluation mode component 430 may be configured as or otherwise support a means for configuring the semiconductor component 420 to operate in a second evaluation mode based at least in part on a temperature indicated by at least one temperature sensor of the semiconductor component 420 satisfying a temperature threshold in response to performing the one or more first operations, the second evaluation mode associated with a lower heat generation than the first evaluation mode. In some examples, the evaluation operation component 435 may be configured as or otherwise support a means for performing one or more second operations of the semiconductor component 420 based at least in part on configuring the semiconductor component 420 to operate in the second evaluation mode.

In some examples, to support configuring the semiconductor component to operate in the second evaluation mode, the transistor configuration component 440 may be configured as or otherwise support a means for increasing a threshold voltage characteristic for one or more transistors of the semiconductor component 420 during the second evaluation mode. In some examples, to support increasing the threshold voltage characteristic for the one or more transistors, the transistor configuration component 440 may be configured as or otherwise support a means for increasing a bias, from one or more voltage sources of the semiconductor component 420, that is applied to one or more wells of the semiconductor component 420 associated with the one or more transistors.

In some examples, the transistor configuration component 440 may be configured as or otherwise support a means for increasing the bias based at least in part on the temperature indicated by the at least one temperature sensor. In some examples, the transistor configuration component 440 may be configured as or otherwise support a means for maintaining a second bias that is applied to one or more second wells of the semiconductor component 420 associated with one or more second transistors of the semiconductor component 420 based at least in part on a second temperature indicated by at least one second temperature sensor of the semiconductor component 420. In some examples, the temperature threshold is lower than a second temperature threshold that is associated with ceasing evaluation operations.

In some examples, the evaluation operation component 435 may be configured as or otherwise support a means for configuring the semiconductor component 420 to cease evaluation operations based at least in part on a second temperature indicated by one or more temperature sensors of the semiconductor component 420 satisfying the second temperature threshold. In some examples, the temperature threshold is higher than a target temperature associated with evaluation of the semiconductor component 420.

In some examples, the evaluation mode component 430 may be configured as or otherwise support a means for comparing temperatures indicated by the at least one temperature sensor with the temperature threshold according to a periodicity. In some examples, the evaluation mode component 430 may be configured as or otherwise support a means for determining that the temperature indicated by the at least one temperature sensor satisfies the temperature threshold based at least in part on the comparing.

In some examples, the register component 445 may be configured as or otherwise support a means for setting a value of a flag of the semiconductor component 420 based at least in part on the temperature satisfying the temperature threshold, where configuring the semiconductor component 420 to operate in the second evaluation mode is based at least in part on the value of the flag. In some examples, the one or more first operations, the one or more second operations, or both are associated with circuitry of the semiconductor component 420 accessing one or more memory arrays of the semiconductor component 420.

In some examples, the indication transmission component 450 may be configured as or otherwise support a means for transmitting a first indication that the semiconductor component 420 is configured to operate in the second evaluation mode, a second indication that the semiconductor component 420 is configured to cease evaluation operations, or both.

In some examples, the described functionality of the semiconductor component 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the semiconductor component 420, or various components thereof, may be implemented at least in part by instructions (e.g., stored in memory, non-transitory computer-readable medium) executable by such at least one processor.

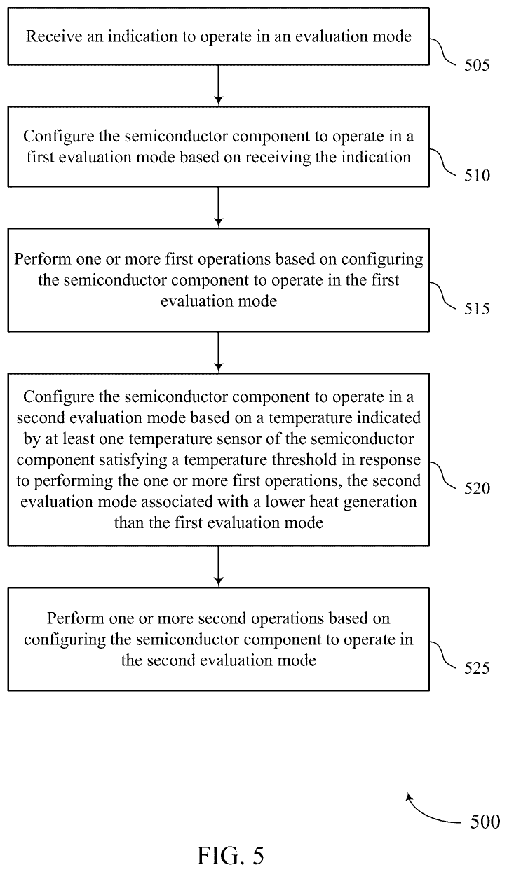

FIG. 5 shows a flowchart illustrating a method 500 that supports heat generation control for memory system evaluation in accordance with examples as disclosed herein. Operations of method 500 may be implemented by a semiconductor component, or an evaluation system, or a combination thereof, as described herein. For example, at least a portion of the operations of method 500 may be performed by a semiconductor component as described with reference to FIGS. 1 through 4. Additionally, or alternatively, at least a portion of the operations of method 500 may be implemented by an evaluation system (e.g., an evaluation controller 225) or its components as described herein. For example, the operations of method 500 may be performed by an evaluation system 200 as described with reference to FIG. 2. In some examples, a semiconductor component or an evaluation system may execute a set of instructions to control the functional elements of the device to perform the described functions. Additionally, or alternatively, the semiconductor component or the evaluation system may perform aspects of the described functions using special-purpose hardware.

At 505, the method may include receiving (e.g., at a semiconductor component, at an evaluation system) an indication to operate in an evaluation mode. In some examples, aspects of the operations of 505 may be performed by an indication reception component 425 as described with reference to FIG. 4.

At 510, the method may include configuring the semiconductor component to operate in a first evaluation mode based at least in part on receiving the indication. In some examples, aspects of the operations of 510 may be performed by an evaluation mode component 430 as described with reference to FIG. 4.

At 515, the method may include performing one or more first operations (e.g., of the semiconductor component, or the evaluation system) based at least in part on configuring the semiconductor component to operate in the first evaluation mode. In some examples, aspects of the operations of 515 may be performed by an evaluation operation component 435 as described with reference to FIG. 4.

At 520, the method may include configuring the semiconductor component to operate in a second evaluation mode based at least in part on a temperature indicated by at least one temperature sensor of the semiconductor component satisfying a temperature threshold in response to performing the one or more first operations, the second evaluation mode associated with a lower heat generation than the first evaluation mode. In some examples, aspects of the operations of 520 may be performed by an evaluation mode component 430 as described with reference to FIG. 4.

At 525, the method may include perform one or more second operations (e.g., of the semiconductor component, of the evaluation system) based at least in part on configuring the semiconductor component to operate in the second evaluation mode. In some examples, aspects of the operations of 525 may be performed by an evaluation operation component 435 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving (e.g., at a semiconductor component, at an evaluation system) an indication to operate in an evaluation mode; configuring the semiconductor component to operate in a first evaluation mode based at least in part on receiving the indication; performing one or more first operations (e.g., of the semiconductor component, of the evaluation system) based at least in part on configuring the semiconductor component to operate in the first evaluation mode; configuring the semiconductor component to operate in a second evaluation mode based at least in part on a temperature indicated by at least one temperature sensor of the semiconductor component satisfying a temperature threshold in response to performing the one or more first operations, the second evaluation mode associated with a lower heat generation than the first evaluation mode; and performing one or more second operations (e.g., of the semiconductor component, of the evaluation system) based at least in part on configuring the semiconductor component to operate in the second evaluation mode.

Aspect 2: The method, apparatus, or non-transitory computer-readable medium of aspect 1, where configuring the semiconductor component to operate in the second evaluation mode further includes operations, features, circuitry, logic, means, or instructions, or any combination thereof for increasing a threshold voltage characteristic for one or more transistors of the semiconductor component during the second evaluation mode.

Aspect 3: The method, apparatus, or non-transitory computer-readable medium of aspect 2, where increasing the threshold voltage characteristic for the one or more transistors includes operations, features, circuitry, logic, means, or instructions, or any combination thereof for increasing a bias, from one or more voltage sources of the semiconductor component, that is applied to one or more wells of the semiconductor component associated with the one or more transistors.

Aspect 4: The method, apparatus, or non-transitory computer-readable medium of aspect 3, further including operations, features, circuitry, logic, means, or instructions, or any combination thereof for increasing the bias based at least in part on the temperature indicated by the at least one temperature sensor and maintaining a second bias that is applied to one or more second wells of the semiconductor component associated with one or more second transistors of the semiconductor component based at least in part on a second temperature indicated by at least one second temperature sensor of the semiconductor component.

Aspect 5: The method, apparatus, or non-transitory computer-readable medium of any of aspects 1 through 4, where the temperature threshold is lower than a second temperature threshold that is associated with ceasing evaluation operations.

Aspect 6: The method, apparatus, or non-transitory computer-readable medium of aspect 5, further including operations, features, circuitry, logic, means, or instructions, or any combination thereof for configuring the semiconductor component to cease evaluation operations based at least in part on a second temperature indicated by one or more temperature sensors of the semiconductor component satisfying the second temperature threshold.

Aspect 7: The method, apparatus, or non-transitory computer-readable medium of any of aspects 1 through 6, where the temperature threshold is higher than a target temperature associated with evaluation of the semiconductor component.

Aspect 8: The method, apparatus, or non-transitory computer-readable medium of any of aspects 1 through 7, further including operations, features, circuitry, logic, means, or instructions, or any combination thereof for comparing temperatures indicated by the at least one temperature sensor with the temperature threshold according to a periodicity and determining that the temperature indicated by the at least one temperature sensor satisfies the temperature threshold based at least in part on the comparing.

Aspect 9: The method, apparatus, or non-transitory computer-readable medium of any of aspects 1 through 8, further including operations, features, circuitry, logic, means, or instructions, or any combination thereof for setting a value of a flag of the semiconductor component based at least in part on the temperature satisfying the temperature threshold, where configuring the semiconductor component to operate in the second evaluation mode is based at least in part on the value of the flag.

Aspect 10: The method, apparatus, or non-transitory computer-readable medium of any of aspects 1 through 9, where the one or more first operations, the one or more second operations, or both are associated with circuitry of the semiconductor component accessing one or more memory arrays of the semiconductor component.

Aspect 11: The method, apparatus, or non-transitory computer-readable medium of any of aspects 1 through 10, further including operations, features, circuitry, logic, means, or instructions, or any combination thereof for transmitting a first indication that the semiconductor component is configured to operate in the second evaluation mode, a second indication that the semiconductor component is configured to cease evaluation operations, or both.

Aspect 12: The method, apparatus, or non-transitory computer-readable medium of any of aspects 1 through 11, further including operations, features, circuitry, logic, means, or instructions, or any combination thereof for placing the semiconductor component and a second semiconductor component in a temperature chamber; receiving (e.g., at the second semiconductor component), a second indication to operate in the evaluation mode; configuring the second semiconductor component to operate in the first evaluation mode based at least in part on receiving the second indication; performing one or more third operations (e.g., of the second semiconductor component) based at least in part on configuring the second semiconductor component to operate in the first evaluation mode; and refraining from configuring the second semiconductor component to operate in the second evaluation mode based at least in part on a second temperature indicated by at least one second temperature sensor of the second semiconductor component failing to satisfy the temperature threshold in response to performing the one or more first operations.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 13: An apparatus, including: one or more memory arrays of a semiconductor component; one or more temperature sensors of the semiconductor component; and circuitry of the semiconductor component coupled with the one or more memory arrays and with the one or more temperature sensors, the circuitry operable to cause the apparatus to (e.g., to cause the apparatus to, to cause the semiconductor component to): receive an indication to operate in an evaluation mode; configure the semiconductor component to operate in a first evaluation mode based at least in part on receiving the indication; perform one or more first operations of the semiconductor component based at least in part on configuring the semiconductor component to operate in the first evaluation mode; configure the semiconductor component to operate in a second evaluation mode based at least in part on a temperature indicated by at least one of the one or more temperature sensors satisfying a temperature threshold in response to performing the one or more first operations, the second evaluation mode associated with a lower heat generation than the first evaluation mode; and perform one or more second operations of the semiconductor component based at least in part on configuring the semiconductor component to operate in the second evaluation mode.

Aspect 14: The apparatus of aspect 13, where, to configure the semiconductor component to operate in the second evaluation mode, the circuitry is operable to: modify (e.g., increase) a threshold voltage characteristic for one or more transistors of the circuitry during the second evaluation mode.

Aspect 15: The apparatus of aspect 14, further including: one or more voltage sources of the semiconductor component, where, to modify the threshold voltage characteristic for the one or more transistors, the circuitry is operable to: increase a bias, from the one or more voltage sources, that is applied to one or more wells of the semiconductor component associated with the one or more transistors.

Aspect 16: The apparatus of aspect 15, where the circuitry is further operable to: increase the bias based at least in part on the temperature indicated by the at least one of the one or more temperature sensors; and maintain a second bias that is applied to one or more second wells of the semiconductor component associated with one or more second transistors of the semiconductor component based at least in part on a second temperature indicated by at least one second temperature sensor of the one or more temperature sensors.

Aspect 17: The apparatus of any of aspects 13 through 16, where the temperature threshold is lower than a second temperature threshold that is associated with ceasing evaluation operations.

Aspect 18: The apparatus of aspect 17, where the circuitry is further operable to: configure the semiconductor component to cease evaluation operations based at least in part on a second temperature indicated by the one or more temperature sensors satisfying the second temperature threshold.

Aspect 19: The apparatus of any of aspects 13 through 18, where the temperature threshold is higher than a target temperature associated with evaluation of the semiconductor component.

Aspect 20: The apparatus of any of aspects 13 through 19, where the circuitry is operable to: compare temperatures indicated by the at least one of the one or more temperature sensors with the temperature threshold according to a periodicity; and determine that the temperature indicated by the at least one of the one or more temperature sensors satisfies the temperature threshold based at least in part on the comparing.

Aspect 21: The apparatus of any of aspects 13 through 20, where the circuitry is further operable to: set a value of a flag of the semiconductor component based at least in part on the temperature satisfying the temperature threshold, where configuring the semiconductor component to operate in the second evaluation mode is based at least in part on the value of the flag.

Aspect 22: The apparatus of any of aspects 13 through 21, where the one or more first operations, the one or more second operations, or both are associated with the circuitry accessing the one or more memory arrays.

Aspect 23: The apparatus of any of aspects 13 through 22, where the circuitry is further operable to: transmit a first indication that the semiconductor component is configured to operate in the second evaluation mode, a second indication that the semiconductor component is configured to cease evaluation operations, or both.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processor. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, that can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or a processor.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
one or more memory arrays of a semiconductor component;
one or more temperature sensors of the semiconductor component; and
circuitry of the semiconductor component coupled with the one or more memory arrays and with the one or more temperature sensors, the circuitry operable to cause the apparatus to:
receive an indication to operate in an evaluation mode;
configure the semiconductor component to operate in a first evaluation mode based at least in part on receiving the indication;
perform one or more first operations of the semiconductor component based at least in part on configuring the semiconductor component to operate in the first evaluation mode;
configure the semiconductor component to operate in a second evaluation mode based at least in part on a temperature indicated by at least one of the one or more temperature sensors satisfying a temperature threshold in response to performing the one or more first operations, the second evaluation mode associated with a lower heat generation than the first evaluation mode; and
perform one or more second operations of the semiconductor component based at least in part on configuring the semiconductor component to operate in the second evaluation mode.

2. The apparatus of claim 1, wherein, to configure the semiconductor component to operate in the second evaluation mode, the circuitry is operable to:
increase a threshold voltage characteristic for one or more transistors of the circuitry during the second evaluation mode.

3. The apparatus of claim 2, further comprising:
one or more voltage sources of the semiconductor component, wherein, to increase the threshold voltage characteristic for the one or more transistors, the circuitry is operable to:
increase a bias, from the one or more voltage sources, that is applied to one or more wells of the semiconductor component associated with the one or more transistors.

4. The apparatus of claim 3, wherein the circuitry is further operable to:
increase the bias based at least in part on the temperature indicated by the at least one of the one or more temperature sensors; and
maintain a second bias that is applied to one or more second wells of the semiconductor component associated with one or more second transistors of the semiconductor component based at least in part on a second temperature indicated by at least one second temperature sensor of the one or more temperature sensors.

5. The apparatus of claim 1, wherein the circuitry is further operable to:
configure the semiconductor component to cease evaluation operations based at least in part on a second temperature indicated by the one or more temperature sensors satisfying a second temperature threshold that is greater than the temperature threshold.

6. The apparatus of claim 1, wherein the circuitry is operable to:
compare temperatures indicated by the at least one of the one or more temperature sensors with the temperature threshold according to a periodicity; and
determine that the temperature indicated by the at least one of the one or more temperature sensors satisfies the temperature threshold based at least in part on the comparing.

7. The apparatus of claim 1, wherein the circuitry is further operable to:
set a value of a flag of the semiconductor component based at least in part on the temperature satisfying the temperature threshold, wherein configuring the semiconductor component to operate in the second evaluation mode is based at least in part on the value of the flag.

8. The apparatus of claim 1, wherein the one or more first operations, the one or more second operations, or both are associated with the circuitry accessing the one or more memory arrays.

9. The apparatus of claim 1, wherein the circuitry is further operable to:
transmit a first indication that the semiconductor component is configured to operate in the second evaluation mode, a second indication that the semiconductor component is configured to cease evaluation operations, or both.

10. A method, comprising:
receiving, at a semiconductor component, an indication to operate in an evaluation mode;
configuring the semiconductor component to operate in a first evaluation mode based at least in part on receiving the indication;
performing one or more first operations of the semiconductor component based at least in part on configuring the semiconductor component to operate in the first evaluation mode;
configuring the semiconductor component to operate in a second evaluation mode based at least in part on a temperature indicated by at least one temperature sensor of the semiconductor component satisfying a temperature threshold in response to performing the one or more first operations, the second evaluation mode associated with a lower heat generation than the first evaluation mode; and
performing one or more second operations of the semiconductor component based at least in part on configuring the semiconductor component to operate in the second evaluation mode.

11. The method of claim 10, wherein configuring the semiconductor component to operate in the second evaluation mode further comprises:
increasing a threshold voltage characteristic for one or more transistors of the semiconductor component during the second evaluation mode.

12. The method of claim 11, wherein increasing the threshold voltage characteristic for the one or more transistors comprises:
increasing a bias, from one or more voltage sources of the semiconductor component, that is applied to one or more wells of the semiconductor component associated with the one or more transistors.

13. The method of claim 12, comprising:
increasing the bias based at least in part on the temperature indicated by the at least one temperature sensor; and
maintaining a second bias that is applied to one or more second wells of the semiconductor component associated with one or more second transistors of the semiconductor component based at least in part on a second temperature indicated by at least one second temperature sensor of the semiconductor component.

14. The method of claim 10, wherein the temperature threshold is higher than a target temperature associated with evaluation of the semiconductor component.

15. The method of claim 10, further comprising:
comparing temperatures indicated by the at least one temperature sensor with the temperature threshold according to a periodicity; and
determining that the temperature indicated by the at least one temperature sensor satisfies the temperature threshold based at least in part on the comparing.

16. The method of claim 10, further comprising:
setting a value of a flag of the semiconductor component based at least in part on the temperature satisfying the temperature threshold, wherein configuring the semiconductor component to operate in the second evaluation mode is based at least in part on the value of the flag.

17. The method of claim 10, wherein the one or more first operations, the one or more second operations, or both are associated with circuitry of the semiconductor component accessing one or more memory arrays of the semiconductor component.

18. The method of claim 10, further comprising:
transmitting a first indication that the semiconductor component is configured to operate in the second evaluation mode, a second indication that the semiconductor component is configured to cease evaluation operations, or both.

19. The method of claim 10, further comprising:
placing the semiconductor component and a second semiconductor component in a temperature chamber;
receiving, at the second semiconductor component, a second indication to operate in the evaluation mode;
configuring the second semiconductor component to operate in the first evaluation mode based at least in part on receiving the second indication;
performing one or more third operations of the second semiconductor component based at least in part on configuring the second semiconductor component to operate in the first evaluation mode; and
refraining from configuring the second semiconductor component to operate in the second evaluation mode based at least in part on a second temperature indicated by at least one second temperature sensor of the second semiconductor component failing to satisfy the temperature threshold in response to performing the one or more first operations.

20. A non-transitory computer-readable medium storing code, the code comprising instructions executable by a processor to:
receive, at a semiconductor component, an indication to operate in an evaluation mode;
configure the semiconductor component to operate in a first evaluation mode based at least in part on receiving the indication;
perform one or more first operations of the semiconductor component based at least in part on configuring the semiconductor component to operate in the first evaluation mode;
configure the semiconductor component to operate in a second evaluation mode based at least in part on a temperature indicated by at least one temperature sensor of the semiconductor component satisfying a temperature threshold in response to performing the one or more first operations, the second evaluation mode associated with a lower heat generation than the first evaluation mode; and
perform one or more second operations of the semiconductor component based at least in part on configuring the semiconductor component to operate in the second evaluation mode.
